(19) United States
(12) Patent Application Publication
(10) Pub. No.: US 2005/0000443 A1
(43) Pub. Date: Jan. 6, 2005

(54) Apparatus for processing a substrate using plasma

(76) Inventor: Dong-Hyun Kim, Seoul (KR)

Correspondence Address: F. CHAU & ASSOCIATES, LLC, 130 WOODBURY ROAD, WOODBURY, NY, 11797, US

(21) Appl. No.: 10/882,094

(22) Filed: Jun. 30, 2004

(30) Foreign Application Priority Data
Jul. 1, 2003 (KR) 2003-44109

(51) Int. Cl. C23C 16/00

(52) U.S. Cl. 118/723 I

(57) ABSTRACT

An apparatus for processing a substrate including a processing chamber having an upper space into which a gas for processing a substrate is introduced and a lower space for exhausting processing plasma used in a process for processing the substrate and a byproduct generated in the process. An upper electrode is disposed in the upper space. The upper electrode changes the processing gas into the processing plasma, and also changes a cleaning gas into cleaning plasma for cleaning a first surface that defines the upper space. The substrate is disposed on a lower electrode. The lower electrode has an upper face defining the upper space. An auxiliary electrode is disposed in the lower space. The auxiliary electrode forms the cleaning plasma in the lower space to clean a second surface defining the lower space.

### CROSS REFERENCE TO RELATED APPLICATION

This application claims priority to Korean Patent Application No 2003-44109, filed on Jul. 1, 2003, which is incorporated herein by reference in its entirety.

### BACKGROUND OF THE INVENTION

1. Field of the invention

The present invention relates, generally, to an apparatus for processing a substrate using plasma. More particularly, the present invention relates to an apparatus for processing a substrate using plasma having a processing chamber in which a substrate is processed using processing plasma and for cleaning the inside of the processing chamber using cleaning plasma.

2. Description of the Related Art

Generally, a semiconductor device is fabricated by a fabrication process for forming a semiconductor die that has an electric circuit formed on a silicon substrate, an electrical die sorting (EDS) process for inspecting electric characteristics of the semiconductor die, and a packaging process for encapsulating and separating the semiconductor die.

The fabrication process includes a plurality of unit processes. The unit processes are repeatedly performed on the substrate to form the semiconductor die. The unit processes include a deposition process, a chemical mechanical polishing (CMP) process, an etching process, an ion implanting process, a cleaning process, etc.

Various layers are formed on the substrate by the deposition process. The deposition process may include a chemical vapor deposition (CVD) process, a plasma enhanced chemical vapor deposition (PECVD) process, a high-density plasma chemical vapor deposition (HDPCVD) process, a physical vapor deposition (PVD) process, etc. In the PECVD process and the HDPCVD process, a layer is formed on the substrate using a processing gas in an excited plasma state.

The various layers are patterned by the etching process to form pattern layers. The etching process may be divided into a wet etching process and a dry etching process. In the wet etching process, a layer formed on the substrate is isotropically etched using an etching solution. In the dry etching process, a layer formed on the substrate is anisotropically etched using plasma.

An apparatus for processing a substrate using plasma includes a processing chamber, an upper electrode, a lower electrode, etc. The substrate is disposed in the processing chamber. A processing gas is introduced into the processing chamber. A source power is applied to the upper electrode to change the processing gas into plasma. A bias power is applied to the lower electrode. An alternating current having a frequency of about 13.56 MHz may be used as the source power. A direct current or an alternating current having a frequency of about 2 MHz may be used as the bias power. Alternatively, the source power may be applied to the lower electrode and the upper electrode may be grounded.

FIG. 1 is a cross sectional view illustrating a conventional apparatus for processing a substrate using plasma.

Referring to FIG. 1, a conventional apparatus 100 includes a processing chamber 102 in which a substrate 10 is disposed, an upper electrode 110 for changing a processing gas into processing plasma, and a lower electrode 120 for inducing the processing plasma onto the substrate 10.

The inside of the processing chamber 102 is divided into an upper space 104 into which the processing gas is introduced and a lower space 106 for exhausting the processing plasma used in a process for processing the substrate 10 and a byproduct generated in the process.

The upper electrode 110 is disposed on an upper portion of the processing chamber 102. The processing gas is provided from a gas source 130 to the upper space 104 through the upper electrode 110. The upper electrode 110 includes a first electrode 112 and a second electrode 114 having a disk shape. A first hole 112a through which the processing gas passes is formed through a center portion of the first electrode 112. A buffer space 116 receiving the processing gas that passes through the first hole 112a is provided between the first and second electrodes 112 and 114. Second holes 114a are formed through the second electrode 114. The processing gas in the buffer space 116is uniformly provided to the upper space 104 of the processing chamber 102 through the second holes 114a.

The lower electrode 120 is disposed in the lower space 106 of the processing chamber 102. The lower electrode 120 has an upper face facing the upper space 104. Namely, the lower electrode 120 is supported by a bottom portion of the processing chamber 102 and extends toward the upper space 104. The substrate 10 is disposed and fixed on the upper face of the lower electrode 120 by a vacuum or an electrostatic force.

The upper electrode 110 is connected to a source power generator 140 for changing the processing gas into the processing plasma. The lower electrode 120 is connected to a bias power generator 150.

The processing chamber 102 is maintained under a predetermined pressure by a vacuum pump 160 while the substrate 10 is processed. The vacuum pump 160 is connected to the lower space 106 of the processing chamber 102.

The processing gas in the upper space 104 of the processing chamber 102 is changed into the processing plasma in a space between the upper and lower electrodes 110 and 120, respectively. The substrate 10 is processed using the processing plasma. The processing plasma and the byproduct are exhausted from the processing chamber 102 through the lower space 106 by the vacuum pump 160. Here, the processing plasma and the byproduct may be deposited on an inner wall of the processing chamber 102 to form an undesired layer 20. The undesired layer 20 contaminates the substrate 10 and causes the failure of the substrate 10.

Accordingly, a cleaning process for removing the undesired layer 20 is periodically required. A cleaning gas is introduced into the upper space 104 of the processing chamber 102 through the upper electrode 110. The cleaning gas is changed into cleaning plasma in a space between the upper and lower electrodes 110 and 120, respectively. The undesired layer 20 is removed using the cleaning plasma. The removed layer 20 is then exhausted from the processing chamber 102 by the vacuum pump 160.

The cleaning plasma may readily remove the undesired layer 20 positioned on the upper inner wall of the processing chamber 102, the lower face of the upper electrode 110 and the upper face of the lower electrode 120. However, the cleaning plasma may not entirely remove the undesired layer 20 positioned on the lower inner wall of the processing chamber 102 and the side face of the lower electrode 120 such that a portion of the undesired layer 20 remains on surfaces defining the lower space 106 of the processing chamber 102.

The remaining layer 20 contaminates the substrate 10 that is subsequently loaded into the processing chamber 102. Further, a time for entirely removing the undesired layer 20 may be too long.

### SUMMARY OF THE INVENTION

In general, exemplary embodiments of the present invention include an apparatus for processing a substrate using plasma capable of cleaning an entire inner wall of a processing chamber and an entire surface of each part included in the processing chamber.

According to exemplary embodiments of the present invention, an apparatus for processing a substrate includes a processing chamber having an upper space into which a gas for processing a substrate is introduced and a lower space for exhausting processing plasma used in a process for processing the substrate and a byproduct generated in the process. An upper electrode is disposed in the upper space. The upper electrode changes the processing gas into processing plasma, and also changes cleaning gas into cleaning plasma for cleaning a first surface that defines the upper space. The substrate is disposed on a lower electrode. The lower electrode has an upper face defining a lower boundary of the upper space. An auxiliary electrode is disposed in the lower space. The auxiliary electrode forms the cleaning plasma in the lower space to clean a second surface defining the lower space.

According to the exemplary embodiments of the present invention, an undesired layer formed on the first and second surfaces may be entirely removed using the cleaning plasma that is formed by the upper electrode and the auxiliary electrode. Therefore, a time interval for periodic cleaning of the processing chamber may be prolonged, and a time for cleaning the processing chamber may be reduced.

These and other exemplary embodiments, features, aspects, and advantages of the present invention will be described and become readily apparent from the following detailed description of exemplary embodiments when read in conjunction with the accompanying drawings.

### BRIEF DESCRIPTION OF THE DRAWINGS

FIG. 1 is a cross-sectional view illustrating a conventional apparatus for processing a substrate using plasma.

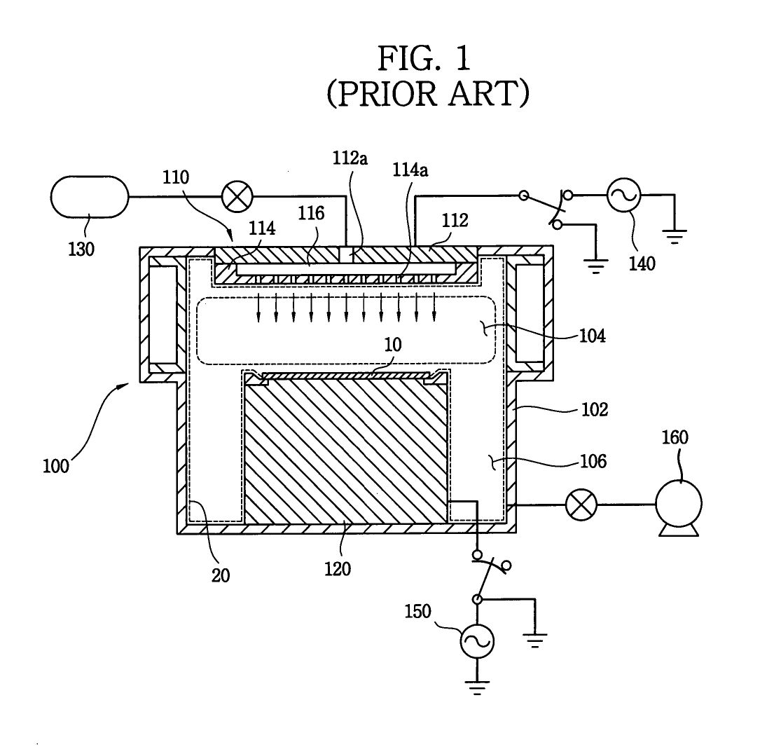

FIG. 2 is a cross-sectional view illustrating an apparatus for processing a substrate using plasma in accordance with a first exemplary embodiment of the present invention.

FIG. 3 is a cross-sectional view illustrating an apparatus for processing a substrate using plasma in accordance with a second exemplary embodiment of the present invention.

FIGS. 4A and 4B are partial cross-sectional views illustrating auxiliary electrodes in accordance with additional exemplary embodiments of the present invention.

### DETAILED DESCRIPTION OF EXEMPLARY EMBODIMENTS

Hereinafter, the present invention will be explained in detail with reference to the accompanying drawings.

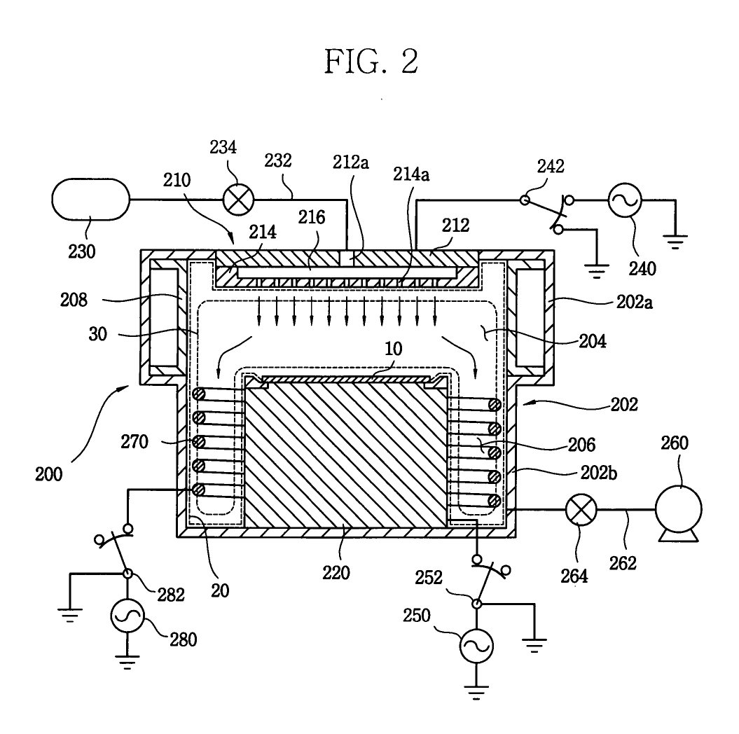

FIG. 2 is a cross-sectional view illustrating an apparatus for processing a substrate using plasma in accordance with a first exemplary embodiment of the present invention.

Referring to FIG. 2, an apparatus 200 for processing a substrate in accordance with a first exemplary embodiment of the present invention includes a processing chamber 202, an upper electrode 210, a lower electrode 220 and an auxiliary electrode 270.

The processing chamber includes an upper space 204 into which a gas for processing a substrate 10 is introduced, and a lower space 206 for exhausting processing plasma used in a process for processing the substrate 10 and a byproduct generated in the process. The upper space 204 is defined by first surfaces and the lower space 206 is defined by second surfaces.

The upper electrode 210 has a first electrode 212 disposed at an upper portion of the processing chamber 202 and a second electrode 214 fixed to a lower face of the first electrode 212. The first electrode 212 and second electrode 214 may have a disk shape. A source current is applied to the first electrode 212. The second electrode 214 has a lower face facing the upper space 204. The upper electrode 210 is connected to a source power generator 240 via a first switch 242.

A first hole 212a is formed through a center portion of the first electrode 212. The first hole 212a is connected to a gas line 232 through which the processing gas or cleaning gas passes. The processing gas or the cleaning gas is introduced into the processing chamber 202 through the first hole 212a. A buffer space 216 is provided between the first and second electrodes 212 and 214, respectively. The buffer space 216 receives the processing gas or the cleaning gas. A gas source 230 in which the processing gas or the cleaning gas is contained is connected to the gas line 232. A valve 234 for controlling a flux of the processing gas or the cleaning gas is mounted in the gas line 232.

Second holes 214a are formed through the second electrode 214. The processing gas or the cleaning gas in the buffer space 216 is introduced into the processing chamber 202 through the second holes 214a. A recess defining the buffer space 216 is formed on the upper face of the second electrode 214.

The lower electrode 220 is disposed on a bottom portion of the processing chamber 202. The substrate 10 is disposed and secured on an upper face of the lower electrode 220. The lower electrode 220 is connected to a bias power generator 250 via a second switch 252.

The processing gas is introduced into the processing chamber 202 from the gas source generator 230 through the gas line 232 and the upper electrode 210. The processing gas is changed into processing plasma in a space between the upper and lower electrodes 210 and 220, respectively. The substrate 10 disposed on the lower electrode 220 is processed using the processing plasma. The processing plasma and the byproduct are exhausted from the processing chamber 202 by a vacuum pump 260. The process for processing the substrate 10 may include a deposition process for forming a layer on the substrate 10, an etching process for partially removing a layer formed on the substrate 10, etc.

A liner 208 is disposed on an upper inner wall 202a of the processing chamber 202. The liner 208 protects the upper inner wall 202a of the processing chamber 202 from the processing plasma. The upper space 204 is defined by the upper electrode 210, the lower electrode 220 and the liner 208. Thus, the first surfaces defining the upper space 204 include the lower face of the upper electrode 210, the inner wall of the liner 208 and the upper face of the lower electrode 220.

The lower space 206 is positioned beneath the upper space 204. The second surfaces defining the lower space 206 include the lower inner wall 202b of the processing chamber 202, the bottom face of the processing chamber 202 and the outer face of the lower electrode 220.

The vacuum pump 260 is connected to the lower space 206 through the lower inner wall 202b of the processing chamber 202. A valve 264 for controlling an inner pressure of the processing chamber 202 is mounted in a vacuum line 262 connected between the processing chamber 202 and the vacuum pump 260.

An undesired layer 20 is formed on the first and second surfaces while the substrate 10 is processed using the processing plasma. The undesired layer 20 is removed using the cleaning plasma. A cleaning gas is introduced into the processing chamber 202 from the gas source 230 through the gas line 232 and the upper electrode 210. The cleaning gas is changed into the cleaning plasma in the space between the upper and lower electrodes 210 and 220, respectively. The cleaning plasma removes the undesired layer 20 formed on the first and second surfaces. The removed layer is exhausted from the processing chamber 202 by the vacuum pump 260.

Here, since the cleaning plasma is formed only in the upper space 204, the cleaning plasma in the upper space 204 may not entirely remove the undesired layer 20 on the second surfaces. To entirely remove the undesired layer 20 on the second surfaces, the auxiliary electrode 270 is disposed in the lower space 206.

Preferably, the auxiliary electrode 270 has a coil shape. The auxiliary electrode 270 is adjacently disposed on the lower inner wall 202b of the processing chamber 202. That is, the auxiliary electrode 270 is wound around the lower electrode 220. The auxiliary electrode 270 expands a region in which the cleaning plasma is formed from the upper space 204 into the lower space 206. An auxiliary power that is lower than the source power is applied to the auxiliary electrode 270. For example, when the source power is about 1,000 watts to about 3,000 watts, the auxiliary power is about 100 watts to about 500 watts. Accordingly, the cleaning plasma is formed in the lower space 206 as well as in the upper space 204. As a result, the cleaning plasma in the lower space 206 entirely removes the undesired layer 20 on the second surfaces.

The auxiliary electrode 270 may include a conductive material such as aluminum. An insulating layer such as oxide is formed on the auxiliary electrode 270. The auxiliary electrode 270 is connected to an auxiliary power generator 280 via a third switch 282.

In this exemplary embodiment, the processing chamber 202 has a cylindrical shape. However, the shape of the processing chamber 202 does not restrict the range of the present invention. Therefore, the auxiliary electrode 270 may be employed in processing chambers having various shapes.

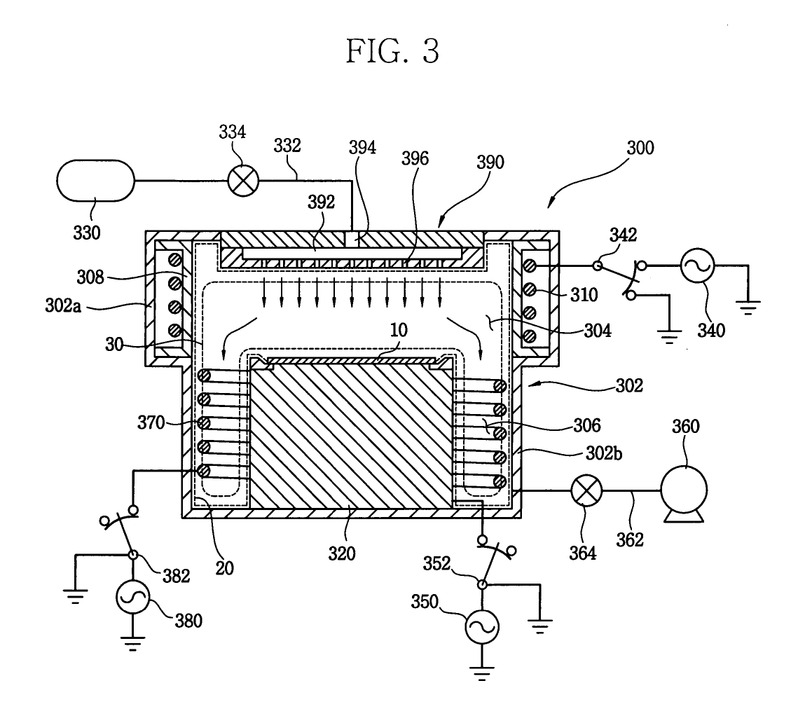

FIG. 3 is a cross-sectional view illustrating an apparatus for processing a substrate using plasma in accordance with a second exemplary embodiment of the present invention.

Referring to FIG. 3, an apparatus 300 for processing a substrate includes a processing chamber 302, an upper electrode 310, a lower electrode 320 and an auxiliary electrode 370.

The processing chamber 302 includes an upper space 304 in which a substrate 10 is disposed and processed using processing plasma, and a lower space 306 for exhausting the processing plasma used in a process for processing the substrate 10 and a byproduct generated in the process. The upper space 304 is defined by first surfaces and the lower space 306 is defined by second surfaces.

A shower head 390 is disposed at an upper portion of the processing chamber 302. A processing gas or a cleaning gas is introduced into the processing chamber 302 via the shower head 390. The shower head 390 includes a buffer space 392 for receiving the processing gas or the cleaning gas, a first hole 394 disposed in a top portion of the shower head 390 for connecting the buffer space 392 to a gas source 330. The shower head 390 also includes second holes 396 disposed in a bottom portion of the shower head 390 for uniformly providing the processing gas or the cleaning gas into the processing chamber 302. Alternatively, the processing gas or the cleaning gas may be introduced into the processing chamber 302 using a gas injector that is disposed at the upper portion or an upper inner wall of the processing chamber 302.

Preferably, the upper electrode 310 has a coil shape. The upper electrode 310 is adjacently disposed at the upper space 304. A liner 308 for protecting the upper inner wall 302a of the processing chamber 302 is disposed along the upper inner wall 302a of the processing chamber 302. The upper electrode 310 is wound around the liner 308. The liner 308 may include an insulating material such as quartz or ceramic. The upper electrode 310 is connected to a source power generator 340 via a first switch 342. Alternatively, when the upper portion of the processing chamber 302 has a dome shape, the upper electrode 310 may be wound around the dome shaped processing chamber 302.

The upper space 304 is defined by the shower head 390, the liner 308 and the lower electrode 320. The first surfaces include a lower face of the shower head 390, an inner wall of the liner 308 and an upper face of the lower electrode 320.

The lower electrode 320 is disposed on a bottom face of the processing chamber 302. A bias power is applied to the lower electrode 320. The substrate 10 is disposed on the upper face of the lower electrode 320. The lower electrode 320 is connected to a bias power generator 350 via a second switch 352.

The lower space 306 is positioned beneath the upper space 304. The second surfaces include a lower inner wall 302b of the processing chamber 302, the bottom face of the processing chamber 302 and an outer face of the lower electrode 320.

The processing gas is introduced into the upper space 304 via the shower head 390. A source power from the source power generator 340 is applied to the upper electrode 310. The processing gas is excited by the upper electrode 310 to form the processing plasma. The substrate 10 disposed on the lower electrode 320 is processed using the processing plasma. The processing plasma and the byproduct are exhausted from the processing chamber 302 through the lower space 306 by a vacuum pump 360.

An undesired layer 20 formed on the first and second surfaces is removed using the cleaning plasma. The cleaning gas is introduced into the upper space 304 of the processing chamber 302 through the shower head 390. The cleaning gas is excited by the upper electrode 310 to form the cleaning plasma. An auxiliary power is applied to the auxiliary electrode 370 to form the cleaning plasma in the lower space 306. A region 30 in which the cleaning plasma is formed is expanded from the upper space 304 into the lower space 306 by the auxiliary electrode 370. Preferably, the auxiliary electrode 370 has a coil shape. The auxiliary electrode 370 is disposed along the lower inner wall 302b of the processing chamber 302. The lower inner wall 302b of the processing chamber 302 may preferably include an insulating material such as quartz or ceramic. The auxiliary electrode 370 is connected to an auxiliary power generator 380 via a third switch 382.

Accordingly, since the cleaning plasma is formed in the lower space 306 as well as in the upper space 304, the cleaning plasma may entirely remove the undesired layer 20 formed on the first and second surfaces.

A gas line 332 is connected between the gas source 330 and the shower head 390. A valve 334 for controlling the flux of the processing gas or the cleaning gas is mounted in the gas line 332. A vacuum line 362 is connected between the vacuum pump 360 and the processing chamber 302. A valve 364 for controlling the flow of vacuum is mounted in the vacuum line 362.

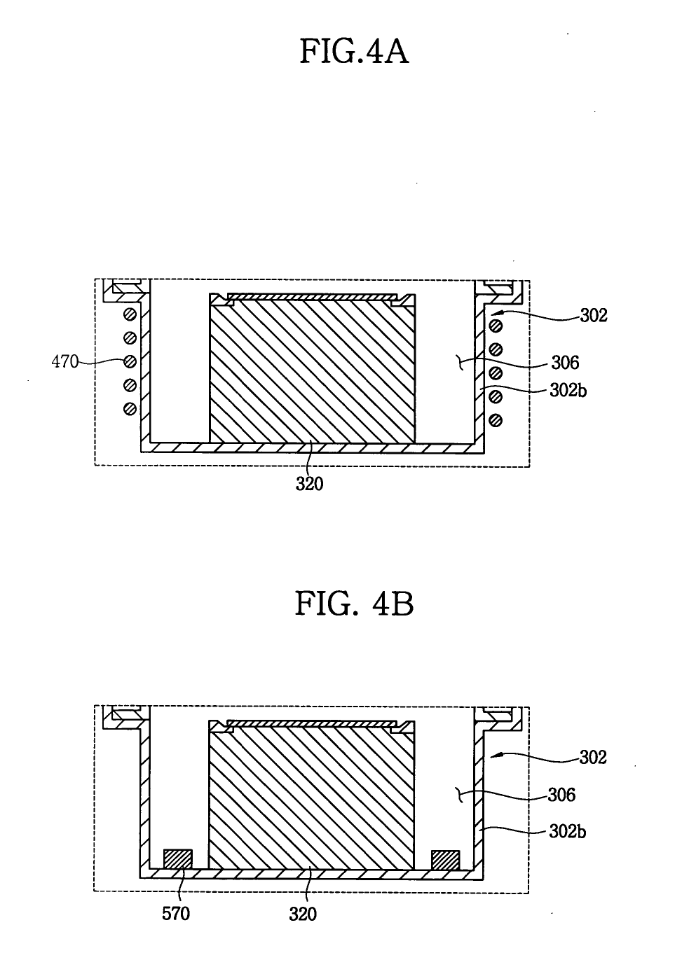

FIGS. 4A and 4B are partial cross-sectional views illustrating auxiliary electrodes in accordance with additional exemplary embodiments of the present invention.

Referring to FIG. 4A, an auxiliary electrode 470 has a coil shape. The auxiliary electrode 370 is wound around the outer face 302b of the processing chamber 302. The auxiliary electrode 470 includes a conductive material such as aluminum. An insulating layer is formed on the auxiliary electrode 470.

Referring to FIG. 4B, an auxiliary electrode 570 has a ring shape. The auxiliary electrode 570 is disposed at the bottom face of the processing chamber 302. The auxiliary electrode 570 includes a conductive material such as aluminum. An insulating layer is formed on the auxiliary electrode 570.

According to the present invention, the undesired layer formed on the first and second surfaces may be entirely and uniformly removed from the first and second surfaces by using cleaning plasma because the cleaning plasma is formed in the lower space as well as in the upper space

Therefore, a time interval for periodic cleaning of the processing chamber may be prolonged, and a time for cleaning the processing chamber may be reduced.

Having described the exemplary embodiments of the present invention, it is noted that modifications and variations can be made by persons skilled in the art in light of the above teachings. It is therefore to be understood that changes may be made in the exemplary embodiments of the present invention disclosed that are is within the scope and the spirit of the invention outlined by the appended claims.

1. An apparatus for processing a substrate using plasma comprising:
a processing chamber having an upper space in which a substrate is processed using processing plasma, and a lower space for exhausting the processing plasma used in a process for processing the substrate and a by-product generated during the process, the upper space being defined by first surfaces and the lower space being defined by second surfaces;
an upper electrode adjacently disposed at the upper space, the upper electrode changing a processing gas into the processing plasma for processing the substrate and a cleaning gas into a cleaning plasma for cleaning first surfaces;
a lower electrode adjacently disposed at the upper space, the substrate being disposed on the lower electrode in the process; and
an auxiliary electrode adjacently disposed at the lower space, the auxiliary electrode expanding a region in which the cleaning plasma is formed from the upper space into the lower space to clean second surfaces.

2. The apparatus claim 1, wherein the upper electrode having a disk shape is disposed at an upper portion of the processing chamber, and the processing gas or the cleaning gas is introduced into the processing chamber through the upper electrode.

3. The apparatus of claim 1, wherein the processing chamber comprises an upper inner wall defining the upper space and a lower inner wall defining the lower space.

4. The apparatus of claim 3, further comprising a liner disposed on the upper inner wall of the processing chamber for protecting the upper inner wall.

5. The apparatus of claim 4, wherein the upper electrode having a coil shape is wound around the liner.

6. The apparatus of claim 1, further comprising a source power generator for providing a source power to the upper electrode to change the processing gas into the processing plasma, and to change the cleaning gas into the cleaning plasma.

7. The apparatus of claim 1, further comprising an auxiliary power generator for providing an auxiliary power to the auxiliary electrode.

8. The apparatus of claim 1, wherein the auxiliary electrode having a coil shape is wound around a lower portion of the processing chamber defining the lower space.

9. The apparatus of claim 1, wherein the auxiliary electrode having a coil shape is disposed at a lower inner wall of the processing chamber defining the lower space.

10. The apparatus of claim 9, further comprising an insulating layer formed on the auxiliary electrode.

11. The apparatus of claim 1, wherein the auxiliary electrode having a ring shape is disposed at a bottom face of the processing chamber.

12. The apparatus of claim 11, further comprising an insulating layer formed on the auxiliary electrode.

13. The apparatus of claim 1, further comprising a vacuum pump connected to the processing chamber for providing vacuum to the processing chamber to exhaust the processing plasma and the byproduct.

14. An apparatus, comprising:
a process chamber for processing a substrate using plasma, wherein the processing chamber has a lower space and an upper space; and
an auxiliary electrode positioned at the lower space of the processing chamber, wherein the auxiliary electrode changes a cleaning gas into a cleaning plasma for cleaning first surfaces defining the lower space.

15. The apparatus of claim 14, further comprising:
an upper electrode positioned at an upper inner sidewall of the processing chamber;
a shower head positioned at a top portion of the processing chamber and adjacent to the upper electrode; and
a lower electrode positioned at a bottom surface of the processing chamber and extended toward the upper space of the processing chamber, wherein the auxiliary electrode is positioned at a lower inner sidewall of the processing chamber.

16. The apparatus of claim 14, wherein the auxiliary electrode is a coil shape and is positioned at a lower inner sidewall of the processing chamber.

17. The apparatus of claim 14, wherein the auxiliary electrode is a ring shape and is positioned at a bottom surface of the processing chamber and adjacent to a lower electrode, wherein the lower electrode is positioned at the bottom surface of the processing chamber and extends toward the upper space of the processing chamber.

18. The apparatus of claim 14, further comprising:
an auxiliary power generator coupled to the auxiliary electrode via a switch.

19. The apparatus of claim 14, wherein the auxiliary electrode is covered with an insulation layer.

20. The apparatus of claim 14, wherein the auxiliary electrode is a coil shape position at an outer sidewall of the processing chamber adjacent to the lower space.

21. The apparatus of claim 15, further comprising a source power generator connected to the upper electrode, wherein the upper electrode changes a processing gas into processing plasma and changes a cleaning gas into cleaning plasma.

22. The apparatus of claim 14, further comprising an upper electrode for changing the cleaning gas into the cleaning plasma for cleaning second surfaces defining the upper space, wherein the cleaning plasma entirely removes an undesired layer from the first and the second surfaces.
